(19) United States
(12) Patent Application Publication
(10) Pub. No.: US 2011/0008963 A1
(43) Pub. Date: Jan. 13, 2011

(54) METHOD FOR MAKING CONDUCTIVE FILM AND FILM MAKING EQUIPMENT

(75) Inventors: CHIN-YUAN LIU, Miao-Li County (TW); SHIH-MING HUANG, Miao-Li County (TW)

Correspondence Address: Altis Law Group, Inc.;ATTN: Steven Reiss, 288 SOUTH MAYO AVENUE, CITY OF INDUSTRY, CA, 91789, US

(73) Assignee: CHIMEI INNOLUX CORPORATION, Miao-Li County (TW)

(21) Appl. No.: 12/790,856

(22) Filed: May 31, 2010

(30) Foreign Application Priority Data
Jul. 8, 2009 (CN) 200910304136.0
Jul. 8, 2009 (CN) 200910304148.3

(51) Int. Cl. H01L 21/3205; B05D 5/12; B05C 11/00

(52) U.S. Cl. 438/680; 427/58; 427/122; 118/33; 257/E21.295

(57) ABSTRACT

The disclosure discloses a method for making a conductive film and a film making equipment. The method includes providing a substrate having two opposite straight sides, a first side connecting the straight sides, and a second side connecting the straight sides and opposite to the first side. A film layer structure is formed on the substrate. A conductive film is formed by pulling out the film layer structure through the first side of the substrate.

### BACKGROUND OF THE DISCLOSURE

1. Field of the Disclosure

The present disclosure relates to a method for making a conductive film and a substrate applying the same.

2. Description of Related Art

A carbon nanotube is comprised of carbon and is a hollow tube having a nano-scale diameter. The carbon nanotube has metallic or semiconductor properties according to the length, the diameter, and the spiral type thereof. Because the carbon nanotube has superior properties mentioned above, it plays an important role in many technical fields.

Currently, methods for fabricating a carbon nanotube comprises an arc-discharge method, a laser ablation method, a chemical vapor deposition (CVD), for example. In one example, in the chemical vapor deposition, a catalyst layer is firstly formed on a wafer having a round shape, and a carbon nanotube is then deposited on the catalyst layer to form a carbon nanotube layer.

FIG. 1A is schematic view of a conventional wafer with a carbon nanotube layer covered thereon, and FIG. 1B is schematic view of a conventional carbon nanotube. Referring to FIGS. 1A and 1B, a film-pulling process is required to pull out a carbon nanotube layer 12 from the wafer 10, and a carbon nanotube film 14 is formed. In detail, a laser ablating process is performed to the carbon nanotube layer 12 along lines A and B, thus an ablated gap is formed between the carbon nanotube layer 12 in the region a and in the region b, and another ablated gap is formed between the carbon nanotube layer 12 in the region b and in the region c. Then, the carbon nanotube layer 12 in the region d is removed through line C as the boundary of the region b and the region d. Thereafter, a guiding ruler is used to adhere to the carbon nanotubes disposed at line C and moves toward direction D. In this step, the carbon nanotubes covering the region b are pulled to form the carbon nanotube film 14. Particularly, the shape of the carbon nanotube film 14 is the same as the shape of the region b and the carbon nanotube film 14 has a curved side 16.

Referring to FIG. 1A, when the carbon nanotubes grow, the entire wafer 10 is covered by the carbon nanotubes. However, only the carbon nanotubes in the region b are utilized, but the carbon nanotubes in the regions a, c and d are not. Accordingly, the material is wasted and the cost is increased. Further, since most of the display devices available in the market are rectangular, the carbon nanotube film 14 in the region e defined by the curved side 16 has to be cut to form a rectangular shape. Then, the carbon nanotube film 14 is processed according to the size of the display device applied. Accordingly, the material is also wasted.

### SUMMARY OF THE DISCLOSURE

Other objects and advantages of the present disclosure can be further illustrated by the technical features broadly embodied and described as follows.

To achieve the objects described above, an embodiment according to the disclosure discloses a method for making a conductive film and a substrate applying the same. The method includes the following steps: A substrate having two opposite straight sides, a first side connecting the straight sides, and a second side connecting the straight sides and opposite to the first side is provided. A film layer structure is formed on the substrate. A conductive film is formed by pulling out the film layer structure through the first side of the substrate, wherein the film layer structure is comprised of a plurality of nano-scale materials.

Other objects and advantages of the disclosure can be further illustrated by the technical features broadly embodied and described as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is schematic view of a conventional wafer with a carbon nanotube layer covered thereon.

FIG. 1B is schematic view of a conventional carbon nanotube film.

FIG. 2 is a schematic view of a substrate according to a first embodiment of the present disclosure.

FIG. 3 is a schematic view of a substrate according to a second embodiment of the present disclosure.

FIG. 4 is a schematic view of a substrate according to a third embodiment of the present disclosure.

FIG. 5 schematically shows a flow diagram illustrating a method for making a conductive film according to a fourth embodiment of the present disclosure.

FIG. 6 is a schematic view illustrating a film-forming device in a film making equipment according to a fifth embodiment of the present disclosure.

### DESCRIPTION OF EMBODIMENTS

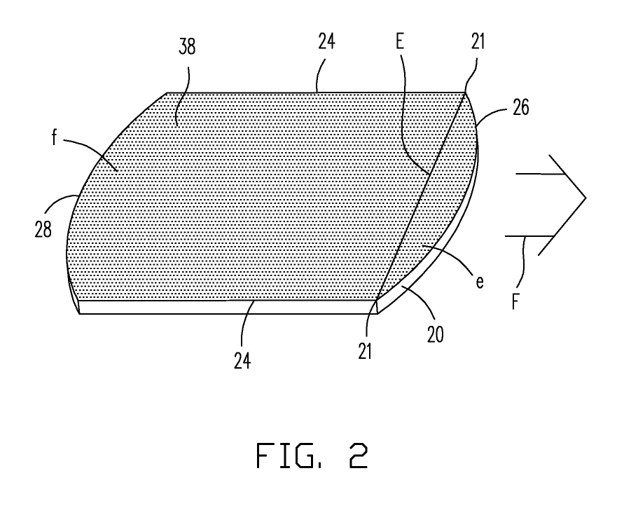

FIG. 2 is a schematic view of a substrate according to a first embodiment of the present disclosure. Referring to FIG. 2, the substrate of the embodiment includes a material containing silicon, such as porous silicon or silicon oxide, where the material containing silicon is used to form a film layer structure 38 on the substrate 20. The film layer structure 38 covers the substrate 20 and is comprised of a plurality of nano-scale materials such as carbon nanotubes. The film layer structure 38 can be formed on the substrate 20 using a variety of methods, such as performing an arc-discharge method, a laser ablation method, a chemical vapor deposition (CVD), for example. Since Van der Waal's forces are formed between the nano-scale materials in the film layer structure 38, a conductive film can be formed while the film layer structure 38 is pulled. Particularly, the conductive film has anisotropic conductivity.

In the first embodiment, the substrate 20 has two opposite straight sides 24, a first side 26 connecting the straight sides 24, and a second side 28 connecting the straight sides 24 and opposite to the first side 26. The straight sides 24 are substantially parallel to each other, and the first side 26 and the second side 28 are curved as shown in FIG. 2, but not limited thereto. That is, the first side 26 and the second side 28 may have other shapes. The first side 26 of the substrate 20 is an outlet from which the film layer structure 38 is pulled out.

In the first embodiment, since the straight sides 24 are substantially parallel to each other, a boundary E between the region e and the region f is firstly defined while a film-pulling process is performed. The boundary E is a straight line, which may be perpendicular to the straight sides 24 and connects two crossover points 21 of the first side 26 and the straight sides 24. Then, nano-scale materials of the film layer structure 38 disposed in the region e is removed. Thereafter, a guiding ruler is used to adhere to the nano-scale materials disposed at the boundary E in the region f and moves toward direction F. Therefore, the nano-scale materials of the film layer structure 38 in the region f are pulled out to form a conductive film. That is, the conductive film is pulled out through the first side 26 of the substrate 20, and the shape of the conductive film is substantially the same as the shape of the region f.

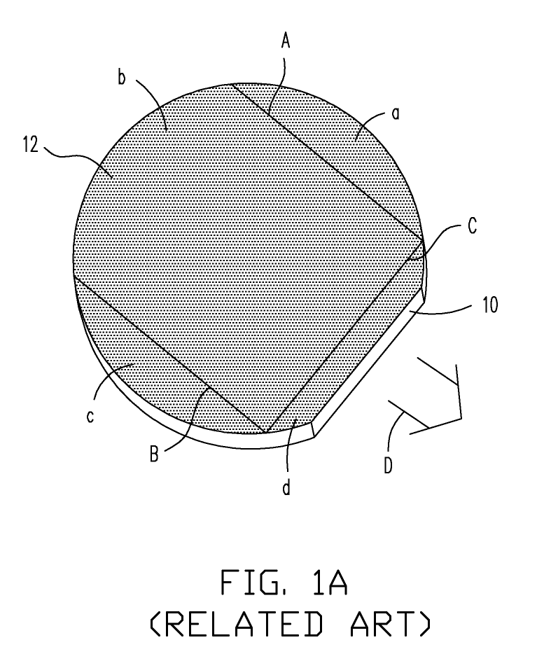

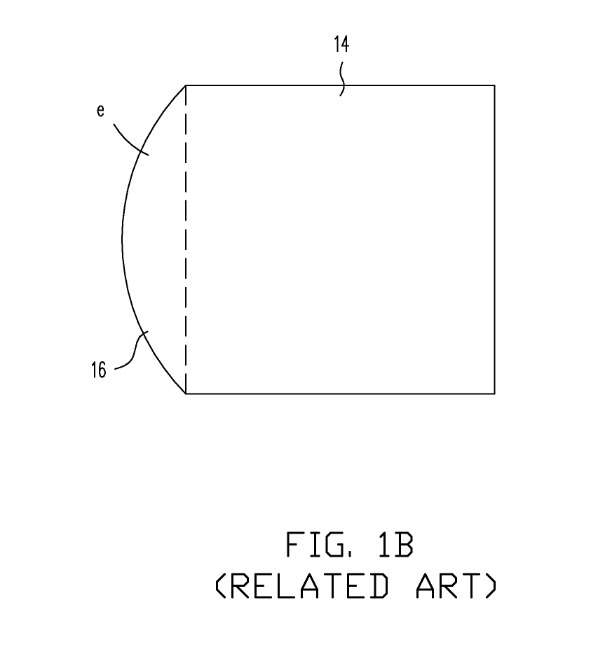

Compared to the wafer 10 used in the conventional technique, the substrate 20 of the first embodiment has two opposite straight sides 24. Thus, after the film layer structure 38 is formed by using the substrate 20 of the first embodiment, the laser ablating process used to form ablated gaps is not required and the carbon nanotubes disposed in the region ranged from the ablated gaps to edge of the wafer 10 as the lines A and B and the regions a and c shown in FIG. 1A are not wasted. Accordingly, the film-pulling process is simplified and the material is saved.

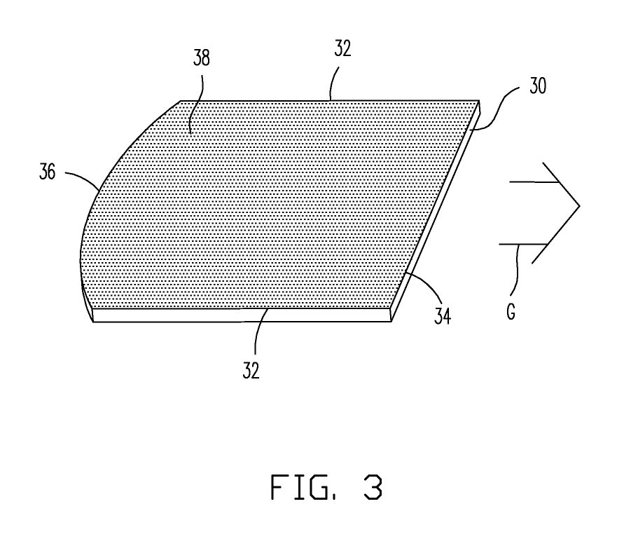

FIG. 3 is a schematic view of a substrate according to a second embodiment of the present disclosure. Referring to FIG. 3, compared to the first embodiment, a material of the substrate 30 of the second embodiment is the same as a material of the substrate 20 of the first embodiment, and the substrate 30 of the second embodiment not only has two opposite straight sides 32 substantially parellel to each other, but also has a first side 34 connecting the straight sides. The first side 34 is straight and perpendicular to the straight sides 32, and a second side 36 connecting the straight sides 32 and opposite to the first side 34 is curved as shown in FIG. 3, for example. However, the shape of the second side 36 is not limited thereto and actually can have any other shapes.

The method for forming a film layer structure 38 on the substrate 30 of the second embodiment is the same as the method used in the first embodiment and is not described repeatedly herein. Since the substrate 30 of the second embodiment has the straight sides 32 substantially parellel to each other and the straight first side 34, a guiding ruler is used to adhere to the nano-scale materials disposed at the first side 34 and moves toward direction G in the film-pulling process. In this process, the film layer structure 38 covering the substrate 30 is pulled out to form a conductive film. That is, the conductive film is pulled out through the first side 34 of the substrate 30, and the shape of the conductive film is substantially the same as the shape of the substrate 30.

Compared to the wafer 10 used in the conventional technique, the substrate 20 of the second embodiment has two opposite straight sides 32 and the straight first side 34. Thus, after the film layer structure 38 is formed by using the substrate 30 of the second embodiment, the laser ablating process used to form ablated gaps as the lines A and B shown in FIG. 1A is not required, the carbon nanotubes disposed in the region ranged from the ablated gaps to edge of the wafer 10 as the regions a and c shown in FIG. 1A are not wasted, and the carbon nanotubes disposed in the region d shown in FIG. 1A are not removed. Accordingly, the film-pulling process is simplified and the material is saved.

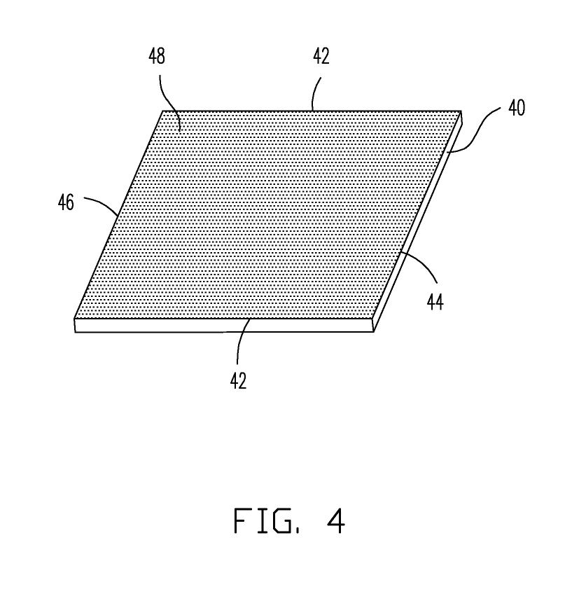

FIG. 4 is a schematic view of a substrate 40 according to a third embodiment of the present disclosure. Referring to FIG. 4, compared to the second embodiment, a material of the substrate 40 of the third embodiment is the same as materials of the substrates of the first and second embodiments, and the substrate 40 of the third embodiment is a rectangle, such as a rectangle different in length and width or a square. The substrate 40 not only has two opposite straight sides 42 substantially parellel to each other, but also has a first side 44 connecting the straight sides 42 and a second side 46 connecting the straight sides 42 and opposite to the first straight side 44, and the first side 44 and the second side 46 are straight and perpendicular to the straight sides 42.

The method for forming a film layer structure 48 on the substrate 40 and the film-pulling method of the third embodiment are the same as the methods used in the second embodiment and have advantages described in the second embodiment, which are not described repeatedly herein. Since the shape of the conductive film is substantially the same as the shape of the substrate, the conductive film formed by using the substrate 40 of the third embodiment is rectangular. Therefore, the conductive film can be processed directly according to the size of the display device applied. That is, the conductive film is not required to be cut to have a rectangular shape before processing. Accordingly, the material is saved and the film-pulling process is simplified.

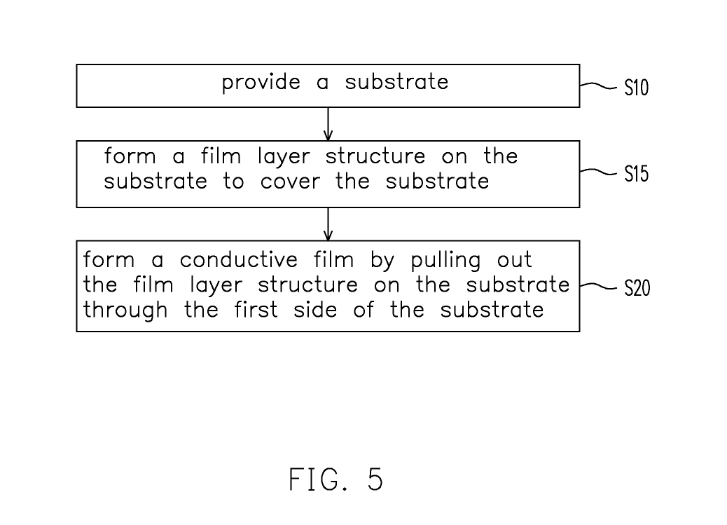

FIG. 5 schematically shows a flow diagram illustrating a method for making a conductive film according to a fourth embodiment of the present disclosure. Referring to FIG. 5, the method for making the conductive film of the fourth embodiment includes the following steps. Firstly, a step S10 is performed, where a substrate is provided. The substrate has two opposite straight sides, a first side connecting the straight sides, and a second side connecting the straight sides and opposite to the first side.

Then, a step S15 is performed, where a film layer structure is formed on the substrate and the substrate is covered by the film layer structure. Thereafter, a step S20 is performed. A conductive film is formed by pulling out the film layer structure on the substrate through the first side of the substrate.

Particularly, the substrate used in the step S10 may be substrate 20, 30 or 40 of the first, second or third embodiment respectively, and the shape and the material of the substrate are not described repeatedly. For example, if the substrate 30 or 40 of the second or third embodiment respectively is used in the step S10, the shape of the conductive film is substantially the same as the shape of the substrate.

In the step S15, the method for forming the film layer structure on the substrate includes an arc-discharge method, a laser ablation method and a chemical vapor deposition (CVD) described above. The following embodiment in which the film layer structure is formed by CVD and the nano-scale materials are carbon nanotubes is exemplified for illustration purposes. Firstly, a catalyst layer is firstly deposited on a substrate. Then, an annealing process is performed. Thereafter, the substrate is entered to a reaction device, and the reaction device is heated in the passivation gas and a carbon source gas is introduced. Then, the reaction device is cooled and the carbon nanotubes are deposited on the catalyst layer, and the film layer structure is formed on the substrate.

In the step S20, the method for pulling the film layer structure to form the conductive film is the same as the adhering method using a guiding ruler described above, for example.

The fifth embodiment of the disclosure provides a film making equipment to implement the method for making the conductive film of a fourth embodiment. The film making equipment includes a substrate, a film-forming device and a film-pulling device. The substrate may be the substrate 20, 30 or 40 of the first, second or third embodiment, and the shape and the material of the substrate are not described repeatedly. The film-forming device is used to form the film layer structure on the substrate, and the film-pulling device is used to pull out the film layer structure on the substrate through the first side of the substrate to form the conductive film.

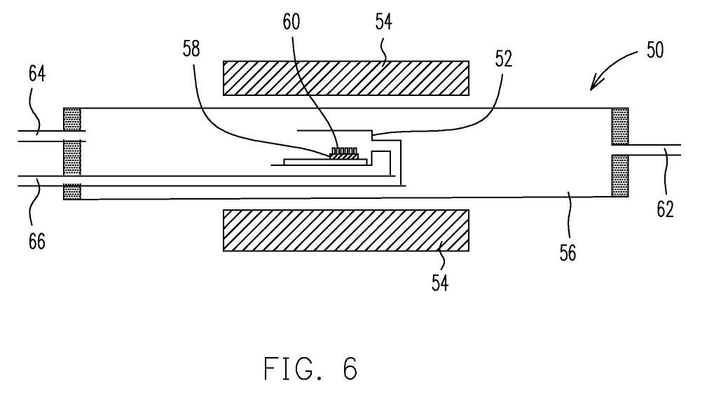

FIG. 6 is a schematic view illustrating a film-forming device in a film making equipment according to a fifth embodiment of the present disclosure. Referring to FIG. 6, the film-forming device 50 includes a reaction device and a loading device 52, and the reaction device includes a heater 54 and a reaction chamber 56, and the loading device 52 includes a material, containing silicon such as a quartz boat. The loading device 52 is installed in the reaction device 56 and capable of loading the substrate 58. The reaction chamber 56 is capable of forming the film layer structure 60 on the substrate 58, and a process forming the film layer structure 60 is a chemical vapor deposition method, for example. The reaction chamber 56 includes an exhaust pipe 62, a first inlet pipe 64, and a second inlet pipe 66, and the carbon source gas is inducted into the reaction chamber 56 through the first inlet pipe 64, the passivation gas is inducted into the reaction chamber 56 through the second inlet pipe 66, and the heater 54 is used to heat the reaction chamber 56.

The film-pulling device includes a guiding ruler and at least a roller, the guide element is capable of adhering to the film layer structure 60, and the roller is capable of driving the guide element to pull out the film layer structure 60 to form the conductive film. Particularly, if the substrate 30 or 40 of the second or third embodiment is used as the substrate 58, the shape of the conductive film is substantially the same as the shape of the substrate.

To summarize, since the substrate of the embodiments of the present disclosure has at least two opposite straight sides, and the conductive film is pulled out through the first side of the substrate. The first side connects the straight sides. Thus, after the film layer structure is formed on the substrate, the laser ablating process used conventionally to form ablated gaps is not performed and the carbon nanotubes in some regions are not wasted while a film-pulling process is performed. Accordingly, the film-pulling process is simplified and the material is also saved.

It will be apparent to those skilled in the art that various modifications and variations can be made to the present disclosure without departing from the scope or spirit of the disclosure. In view of the foregoing, it is intended that the present disclosure cover modifications and variations of this disclosure provided they fall within the scope of the following claims and their equivalents. Any of the embodiments or any of the claims of the disclosure does not need to achieve all of the advantages or features disclosed by the present disclosure. Moreover, the abstract and the headings are merely used to aid in searches of patent files and are not intended to limit the scope of the claims of the present disclosure.

What is claimed is:

1. A method for making a conductive film, comprising:
providing a substrate having two opposite straight sides, a first side connecting the two opposite straight sides, and a second side connecting the two opposite straight sides and opposite to the first side;
forming a film layer structure on the substrate; and
pulling out the film layer structure on the substrate through the first side of the substrate to form a conductive film.

2. The method for making a conductive film as claimed in claim 1, wherein the film layer structure is comprised of a plurality of nano-scale materials.

3. The method for making a conductive film as claimed in claim 2, wherein the nano-scale materials are carbon nanotubes.

4. The method for making a conductive film as claimed in claim 1, wherein the substrate is covered by the film layer structure, and a shape of the conductive film is substantially the same as a shape of the substrate.

5. The method for making a conductive film as claimed in claim 4, wherein the first side is straight.

6. The method for making a conductive film as claimed in claim 5, wherein the substrate is substantially rectangular.

7. The method for making a conductive film as claimed in claim 1, wherein the substrate comprises a material containing silicon.

8. The method for making a conductive film as claimed in claim 1, wherein the step of forming the film layer structure on the substrate comprises performing a vapor deposition process.

9. A film making equipment, comprising:
a substrate having two opposite straight sides, a first side connecting the two opposite straight sides, and a second side connecting the two opposite straight sides and opposite to the first side;
a film-forming device, capable of forming a film layer structure on the substrate; and
a film-pulling device, capable of pulling out the film layer structure on the substrate through the first side of the substrate to form a conductive film.

10. The film making equipment as claimed in claim 9, wherein the substrate is covered by the film layer structure, and a shape of the conductive film is substantially the same as a shape of the substrate.

11. The film making equipment as claimed in claim 10, wherein the first side is straight.

12. The film making equipment as claimed in claim 11, wherein the substrate is substantially rectangular.

13. The film making equipment as claimed in claim 9, wherein the film layer structure is comprised of a plurality of nano-scale materials.

14. The film making equipment as claimed in claim 13, wherein the nano-scale materials are carbon nanotubes.

15. The film making equipment as claimed in claim 9, wherein the substrate comprises a material containing silicon.

16. The film making equipment as claimed in claim 9, further comprises a loading device and a reaction device, wherein the loading device is installed in the reaction device and capable of loading the substrate, and the reaction device is capable of forming the film layer structure on the substrate.

17. The film making equipment as claimed in claim 16, wherein the reaction device is capable of performing a vapor deposition process.

18. The film making equipment as claimed in claim 16, wherein the loading device comprises a material containing silicon.

19. The film making equipment as claimed in claim 9, wherein the film-pulling device comprises a guide element and at least a roller, the guide element is capable of adhering to the film layer structure, and the roller is capable of driving the guide element.
